(19) United States
(12) Patent Application Publication
(10) Pub. No.: US 2024/0152003 A1
(43) Pub. Date: May 9, 2024

(54) DISPLAY PANEL, METHOD OF MANUFACTURING DISPLAY PANEL, AND PHOTOMASK

(71) Applicant: TCL CHINA STAR OPTOELECTRONICS TECHNOLOGY CO., LTD., Shenzhen (CN)

(72) Inventors: Ying LU, Shenzhen (CN); Yingchun ZHAO, Shenzhen (CN); Wuguang LIU, Shenzhen (CN); Lixia LI, Shenzhen (CN)

(73) Assignee: TCL CHINA STAR OPTOELECTRONICS TECHNOLOGY CO., LTD., Shenzhen (CN)

(21) Appl. No.: 18/192,599

(22) Filed: Mar. 29, 2023

(30) Foreign Application Priority Data
Nov. 9, 2022 (CN) 202211401138.3

(51) Int. Cl. G02F 1/1335; G03F 1/52

(52) U.S. Cl. CPC G02F 1/133553; G03F 1/52; G02F 2203/02

(57) ABSTRACT

Disclosed are a display panel, a method of manufacturing a display panel, and a photomask, wherein the display panel includes a substrate; a driving element layer disposed on a surface of the substrate; an organic layer disposed on a surface of the driving element layer away from the substrate, wherein the organic layer includes a plurality of first convex structures, and each of the first convex structures has an arcuate first sidewall from bottom to top; a reflective layer disposed on a side of the organic layer away from the driving element layer, wherein the reflective layer includes a plurality of second convex structures, each of the second convex structures includes a second side wall corresponding to the first side wall.

### CROSS-REFERENCE OF RELATED APPLICATION

This application claims the benefit of priority of Chinese Patent Application No. 202211401138.3 filed on Nov. 9, 2022, the contents of which are incorporated herein by reference in their entirety.

### TECHNICAL FIELD

The present disclosure relates to the field of display, and in particular, to a display panel, a method of manufacturing a display panel, and a photomask.

### BACKGROUND

Liquid crystal displays (LCDs) can be divided into transmissive displays and reflective displays according to different light sources. With the increasing demand for low-power outdoor displays, the reflective liquid crystal display gradually shows their market prospects. Compared with the transmissive liquid crystal display, the reflective liquid crystal display can be clearly displayed under ambient light without the need of a backlight source, thereby exhibiting the advantages of light weight of body and low power consumption.

However, current reflective liquid crystal displays have low reflectivity to ambient light.

### SUMMARY

An embodiment of the present disclosure provides a display panel, which can solve the problem that the reflective liquid crystal display has low reflectivity to ambient light.

An embodiment of the present disclosure provides a display panel including:
a substrate;
a driving element layer disposed on a surface of the substrate;
an organic layer disposed on a surface of the driving element layer away from the substrate, wherein the organic layer includes a plurality of first convex structures, and each of the first convex structures has an arcuate first sidewall from bottom to top;
a reflective layer disposed on a side of the organic layer away from the driving element layer, wherein the reflective layer includes a plurality of second convex structures, each of the second convex structures includes a second side wall corresponding to the first side wall.

Optionally, the first side wall includes a bottom wall, a first inclined wall, and an outer wall connected in sequence, and an inclination angle of the first inclined wall is in a range of greater than 0° and less than or equal to 10°.

Optionally, the second side wall includes a second inclined wall corresponding to the first inclined wall, and an inclination angle of the second inclined wall is equal or substantially equal to the inclination angle of the first inclined wall.

Optionally, a curvature of the first side wall is greater than a curvature of the second side wall.

Optionally, each of the first convex structures includes a first convex ring connected to the outer wall, each of the second convex structures includes a second convex ring corresponding to the first convex ring, and a diameter of the second convex ring is less than a diameter of the first convex ring.

Optionally, the plurality of second convex structures are arranged in an array; or
the plurality of second convex structures are arranged in M rows by N columns, the second convex structures in two adjacent rows are arranged in a staggered manner, and both of M and N are integers greater than 0.

An embodiment of the present disclosure further provides a method of manufacturing a display panel, including:
disposing a material of an organic layer on a driving element layer;
treating the material of the organic layer with a photomask to form the organic layer having a plurality of first convex structures, wherein each of the first convex structures has an arcuate first sidewall from bottom to top, the first sidewall includes a bottom wall, a first inclined wall, and an outer wall connected in sequence, and the first inclined wall has an inclination angle less than a preset inclination angle;
disposing a reflective layer on a side of the organic layer away from the driving element layer, wherein the reflective layer includes a plurality of second convex structures, each of which corresponds to each of the first convex structures, and each of the second convex structures includes a second side wall corresponding to the first side wall.

Optionally, the inclination angle of the first inclined wall is in a range of greater than 0° and less than or equal to 10°.

Optionally, the step of disposing the reflective layer on the side of the organic layer away from the driving element layer includes:
disposing a reflective material on a side of the first inclined wall away from the driving element layer to form a second inclined wall, wherein the second inclined wall has an inclination angle equal or substantially equal to the inclination angle of the first inclined wall.

Optionally, each of the first convex structures includes a first convex ring connected to the outer wall, each of the second convex structures includes a second convex ring corresponding to the first convex ring, and a diameter of the second convex ring is less than a diameter of the first convex ring.

Optionally, the second convex structures are arranged in an array; or
the second convex structures are arranged in M rows by N columns, the second convex structures in two adjacent rows are arranged in a staggered manner, and both of M and N are integers greater than 0.

An embodiment of the present disclosure further provides a photomask for fabricating an organic layer in a display panel, including:
a light-transmitting layer configured to allow an ultraviolet light to transmit, wherein the light-transmitting layer includes a first light-transmitting portion and at least one annular second light-transmitting portion disposed around the first light-transmitting portion;
a light-shielding layer disposed in an area adjacent to the first light-transmitting portion and the second light-transmitting portion, wherein the light-shielding layer is configured to shield the ultraviolet light.

Optionally, the light-transmitting layer further includes:
a plurality of stripe-shaped third light-transmitting portions, wherein the plurality of third light-transmitting portions are arranged parallel to each other along a length direction of the photomask.

The present disclosure has the advantages that: by disposing the first convex structures on the organic layer, allowing each of the first convex structures to have the arcuate first side wall from bottom to top, disposing the reflective layer on a side of the first convex structures to allow the reflective layer to have the second convex structures, allowing each of the second convex structures to include the second side wall corresponding to the first side wall, a diffuse reflection effect is increased by the arcuate second side wall, so that more ambient light is reflected onto the display surface of the display panel, thereby improving the reflectivity to the ambient light.

### BRIEF DESCRIPTION OF THE DRAWINGS

FIG. 1 is a schematic flowchart of a method of manufacturing a display panel according to an embodiment of the present disclosure.

FIG. 2 is a schematic first flowchart of manufacturing a photomask in the manufacturing method shown in FIG. 1.

FIG. 3 is a schematic second flowchart of manufacturing a photomask in the manufacturing method shown in FIG. 1.

FIG. 4 is a schematic third flowchart of manufacturing a photomask in the manufacturing method shown in FIG. 1.

FIG. 5 is a schematic structural diagram of a display panel according to an embodiment of the present disclosure.

FIG. 6 is a schematic structural diagram of first convex structures in the display panel shown in FIG. 5.

FIG. 7 is a schematic diagram of a first configuration of a photomask according to an embodiment of the present disclosure.

FIG. 8 is a schematic diagram of a second configuration of a photomask according to an embodiment of the present disclosure.

FIG. 9 is a schematic diagram of a third configuration of a photomask according to an embodiment of the present disclosure.

FIG. 10 is a schematic diagram of a fourth configuration of a photomask according to an embodiment of the present disclosure.

FIG. 11 is a schematic diagram of a fifth configuration of a photomask according to an embodiment of the present disclosure.

### DETAILED DESCRIPTION OF THE EMBODIMENTS

The technical solutions in the embodiments of the present disclosure will be clearly and completely described with reference to the accompanying drawings of the present disclosure. It will be apparent that the described embodiments are only a part of the embodiments, rather than all embodiments of the present disclosure. Based on the embodiments in the present disclosure, all other embodiments obtained by a person skilled in the art without involving any inventive effort are within the scope of the present disclosure.

In the description of the present disclosure, it is to be understood that the azimuth or positional relationship indicated by the terms such as “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, is based on the azimuth or positional relationship shown in the drawings. The terms are used to merely facilitate the description of the present disclosure and to simplify the description, and are not intended to indicate or imply that the components or elements referred to are required to have a specific azimuth, or be constructed and operated in a particular azimuth. Accordingly, the terms should not be construed as limiting the present disclosure. Furthermore, the terms “first” and “second” are used for descriptive purposes only and are not to be construed as indicating or implying relative importance or implying the number of indicated technical features. Thus, a feature that limited by “first”, “second” may expressly or implicitly include one or more features. In the description of the present disclosure, “a plurality of” means two or more, unless expressly and specifically defined otherwise.

At present, reflective liquid crystal display panels generally have a problem, i.e., a relatively low reflectivity, which can achieve a maximum level of 10% or less in mass production thereof in the industry. The main reason for this is that light is reflected through multiple paths and has serious energy loss, and finally, the amount of emitting light reaching only 10% of the amount of incident light.

Therefore, in order to solve the above problem, the present disclosure provides a method of manufacturing a display panel, a display panel, and a photomask. The present disclosure is further described below with reference to the accompanying drawings and embodiments.

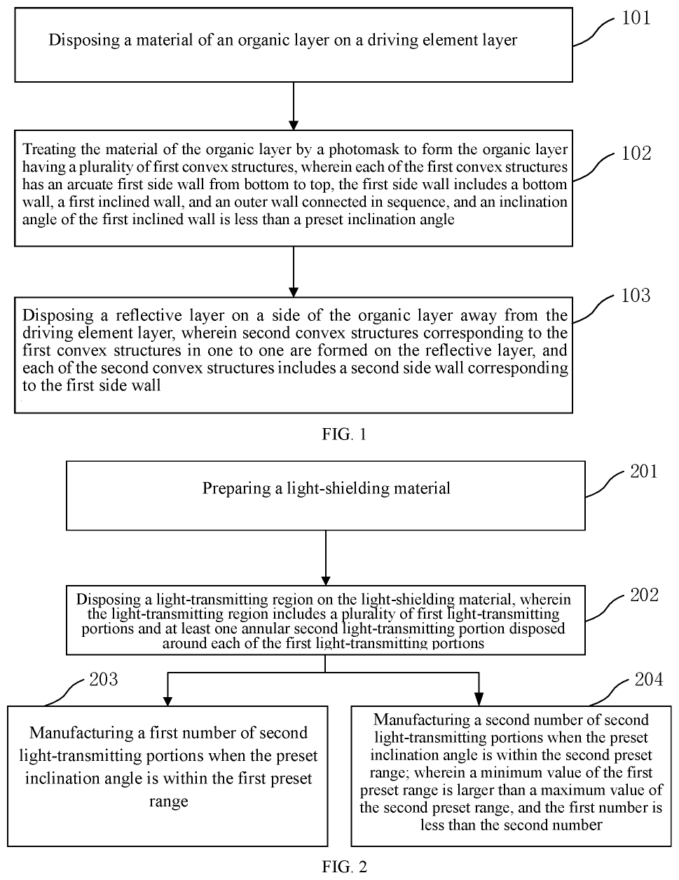

Referring to FIG. 1, it is a schematic flowchart of a method of manufacturing a display panel according to an embodiment of the present disclosure. An embodiment of the present disclosure provides a method of manufacturing a display panel. The display panel manufactured by the method can solve the problem of low reflectivity of the reflective liquid crystal display to ambient light. The manufacturing method is specifically carried out as follows:

101. Disposing a material of an organic layer on a driving element layer.

The material of the organic layer 30 is laid on the prepared driving element layer to a certain thickness, so as to prepare the organic layer 30 subsequently by a photomask 6.

It is to be understood that the material of the organic layer 30 may be selected from materials having photosensitivity and leveling property to facilitate the fabrication of concave and convex shapes through exposure, development, and etching by the photomask 6. For example, the material of the organic layer 30 may be PLN, that is, a material for a flat layer or an insulating layer, such as polyimide (PI). For another example, the material of the organic layer 30 may be a polymer film on array (PFA) on the driving element layer.

102. Treating the material of the organic layer by the photomask to form the organic layer having a plurality of first convex structures, wherein each of the first convex structures has an arcuate first side wall from bottom to top, the first side wall includes a bottom wall, a first inclined wall, and an outer wall connected in sequence, and an inclination angle of the first inclined wall is less than a preset inclination angle.

The material of the organic layer 30 is exposed, developed and etched by the photomask 6 to form the organic layer 30 having the plurality of first convex structures 310, and the inclination angle θ of the first inclined wall 3112 in each of the first convex structures 310 conforms to the preset inclination angle, so that an inclination angle of second convex structures in a reflective layer disposed on the first convex structures 310 can also conform to the preset inclination angle, thereby eliminating total reflection. Therefore, light which is not reflected at the critical angle of the total reflection is reflected out, thereby improving the utilization rate of light, and improving the reflectivity.

It is to be noted that the inclination angle θ of the first inclined wall 3112 conforming to the preset inclination angle can be explained as the inclination angle θ of the first inclined wall 3112 being within the preset inclination angle range, which may be present in a certain error range. The specific error range may be determined according to the actual situation, and is not specifically limited herein.

The preset inclination angle of the first inclined wall 3112 is in a range of greater than 0° and less than or equal to 10°. By setting the preset inclination angle of the first inclination wall 3112 within 10°, total reflection can be eliminated to reflect out the light which is not reflected at the critical angle in the total reflection, thereby improving the utilization rate of light, and improving the reflectivity.

It is to be noted that, the inclination angle of the first inclined wall 3112 is the largest among the respective inclination angles of the bottom wall 3111, the first inclined wall 3112 and the outer wall 3113. The inclination angle of the first inclined wall 3112 is an included angle between the first inclined wall 3112 and a horizontal plane with the horizontal plane as a reference. The included angle is an acute angle.

It is to be understood that the photomask may be directly selected as desired or may be manufactured according to the preset inclination angle.

Illustratively, the organic layer 30 is prepared using the photomask 6 such that the organic layer 30 has the plurality of first convex structures 310, each having the arcuate first side wall 311 from bottom to top. The first side wall 311 includes the bottom wall 3111, the first inclined wall 3112, and the outer wall 3113 connected in sequence. The inclination angle θ of the first inclined wall 3112 can be adjusted according to different photomasks 6. That is, when the display panel 100 is manufactured, the preset inclination angle of the first inclination wall 3112 can be first determined, the photomask 6 is then manufactured according to the preset inclination angle, so that the inclination angle θ the first inclination wall 3112 of the organic layer 30 manufactured by the photomask 6 conforms to the preset inclination angle.

Illustratively, if the preset inclination angle is within a first preset range, the photomask 6 may be manufactured according to a first mode. Alternatively, if the preset inclination angle is within a second preset range, the photomask 6 may be manufactured according to a second mode. The first preset range do not overlap with the second preset range, and the first mode is different from the second mode. When the photomask 6 is used to manufacture the desired organic layer 30, only one photomask 6 is needed to achieve formation of the first convex structures 310, which is simple in process and cost-effective.

103. Disposing the reflective layer on a side of the organic layer away from the driving element layer, wherein second convex structures corresponding to the first convex structures in one to one are formed on the reflective layer, and each of the second convex structures includes a second side wall corresponding to the first side wall.

In an embodiment of the present disclosure, the display panel 100 may be a liquid crystal display (LCD). The incident ambient light is reflected by the reflective layer 40 on the driving element layer, thereby realizing displaying of the display panel 100. The reflective layer 40 is disposed on a side of the driving element layer facing a liquid crystal layer. Liquid crystal molecules in the liquid crystal layer can be used as a switch to control the amount of light emitted from the reflective layer 40, and then to control parameters of the display panel 100, such as display brightness or display gray scale.

In an embodiment of the present disclosure, the reflective layer 40 has the second convex structures 410. In order to facilitate the fabrication of the second convex structures 410 of the reflective layer 40, and to make the surfaces of the second convex structures 410 relatively smooth, the organic layer 30 having the first convex structures 310 can be manufactured first, and then the reflective layer 40 is manufactured, so that the reflective layer 40 has the second convex structures 410.

A reflective material is provided on a side of the first inclined wall 3112 away from the driving element layer to form the second inclined wall, so that the inclination angle of the second inclined wall is equal or substantially equal to the inclination angle of the first inclined wall. Further, the inclination angle of the second inclined wall may range from greater than 0° and less than or equal to 10°, thereby enabling the second convex structures 410 to better reflect ambient light.

Therefore, in an embodiment of the present disclosure, the reflective layer 40 is disposed on the side of the organic layer 30 away from the driving element layer. The second convex structures 410 corresponding to the first convex structures 310 in one to one are formed on the reflective layer 40. The second side wall corresponding to the first side wall 311 of each of the first convex structures 310 is formed in each of the second convex structures 410, and the shape of the second side wall is the same as that of the first side wall 311. The second inclined wall corresponding to the first inclined wall 3112 is formed on the second side wall, and the inclination angle θ of the first inclined wall 3112 is the same as the inclination angle θ of the second inclined wall.

The second convex structures 410 can reflect the incident ambient light onto the display surface of the display panel 100. In addition, the formation of the second convex structures 410 on the reflective layer 40 can increase diffuse reflection and improve the angle of view field. Further, the inclination angle θ of the second inclined wall can be adjusted by adjusting the inclination angle θ of the first inclined wall 3112 in each of the first convex structures 310, so as to change the inclination angle θ of the second inclined wall, thereby reflecting out the ambient light which cannot be reflected out of the second convex structures 410, and improving the utilization rate of light.

In an embodiment of the present disclosure, the formation of the second convex structures 410 on the reflective layer 40 improves the diffuse reflection effect, so that more ambient light is reflected to the display surface of the display panel 100, thereby improving the reflectivity to the ambient light. In addition, before the organic layer 30 is manufactured, the preset angle of the first convex structures 310 of the organic layer 30 is determined. The photomask 6 is manufactured according to the preset angle or directly acquired, whereby the inclination angle θ of the first convex structures 310 of the organic layer 30 is adjusted so that the inclination angle θ of the second convex structures 410 disposed above the organic layer 30 can also be adjusted accordingly. By setting the inclination angle θ of the second convex structures 410 within the preset range, total reflection can be eliminated, so that ambient light which is not reflected at the critical angle in the total reflection is reflected out, thereby improving the utilization rate of light and further improving the reflectivity.

The photomask for fabricating the organic layer includes a plurality of first light-transmitting portions and at least one annular second light-transmitting portion disposed around each of the first light-transmitting portions. Each of the first light-transmitting portions includes a first outer edge adjacent to the corresponding second light-transmitting portion, and each of the at least one second light-transmitting portion includes an inner edge adjacent to the corresponding first light-transmitting portion and a second outer edge away from the first light-transmitting portion. A distance between the first outer edge and the inner edge is a first length, and a distance between the inner edge and the second outer edge is a second length.

The preset angle is positively correlated with the ratio of the first length to the second length. The preset angle is negatively correlated with the number of the second light-transmitting portions of the photomask.

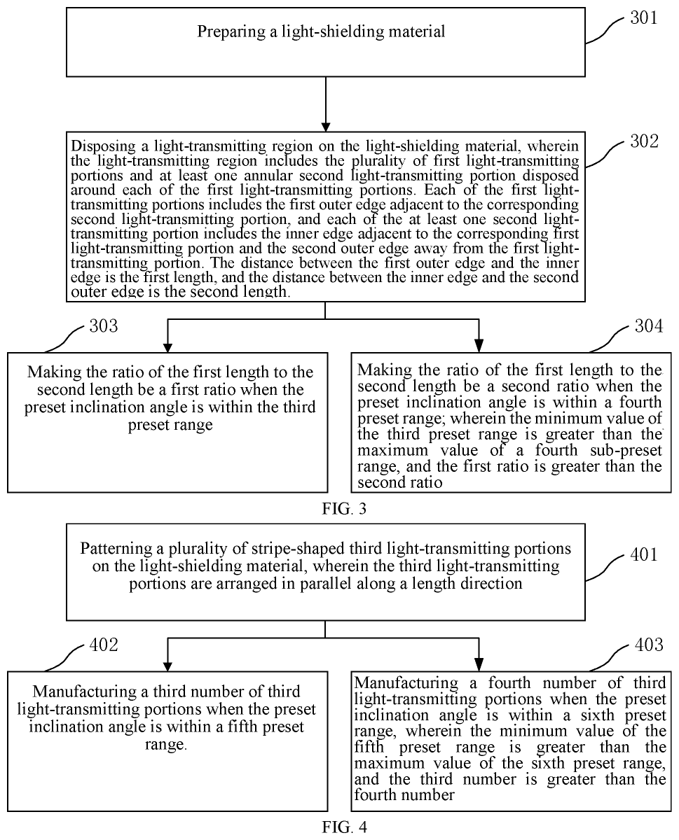

In the case where the photomask 6 is manufactured according to the preset inclination angle, reference may be continued to FIGS. 2 to 4. FIG. 2 is a schematic first flowchart of manufacturing a photomask in the manufacturing method shown in FIG. 1. FIG. 3 is a schematic second flowchart of manufacturing a photomask in the manufacturing method shown in FIG. 1. FIG. 4 is a schematic third flowchart of manufacturing a photomask in the manufacturing method shown in FIG. 1. In some embodiments, as shown in FIG. 2, manufacturing the photomask according to the preset inclination angle includes the following steps:

201. Preparing a light-shielding material.

The light-shielding material is preferably a black ink. The use of the black ink has an advantageous of low cost, and thus the cost can be reduced. Certainly, other light-shielding materials may be used in a specific implementation process, which is not listed here.

202. Disposing a light-transmitting region on the light-shielding material, wherein the light-transmitting region includes the plurality of first light-transmitting portions and at least one annular second light-transmitting portion disposed around each of the first light-transmitting portions.

The light-transmitting region is disposed on the light-shielding material. The light-transmitting region may include the plurality of first light-transmitting portions 601 and at least one annular second light-transmitting portion 602 disposed around each of the first light-transmitting portions 601. It is to be noted that the at least one annular second light-transmitting portion 602 may be one annular second light-transmitting portion 602, two second light-transmitting portions 602, three second light-transmitting portions 602, or the like. The specific number of the second light-transmitting portions 602 may be set according to an actual condition, which is not specifically limited herein.

It is to be noted that when the number of the second light-transmitting portions 602 is greater than or equal to two, the shape and size of each of the second light-transmitting portions 602 may be the same as or different from each other. Specifically, the second light-transmitting portions 602 may be disposed according to an actual condition, and are not specifically limited herein.

It is to be understood that the shape of each of the first light-transmitting portions 601 may be any one of a circular, a square, or an irregular shape. The specific shapes are designed according to the actual situation, and are not specifically limited herein. In addition, the shape of each of the second light-transmitting portions 602 may be any one of a circular, a square, or an irregular shape. The shapes of the second light-transmitting portions 602 may be the same as or different from each other. The specific shapes thereof are designed according to the actual situation, and are not specifically limited herein. The square shape may be a polygon shape, such as a triangle, a quadrangle, a pentagon, or a hexagon shape. 203. Manufacturing a first number of second light-transmitting portions when the preset inclination angle is within the first preset range.

When the preset inclination angle of the first inclined wall 3112 is within the first preset range, the first number of second light-transmitting portions 602 are manufactured. The first number is greater than or equal to 1.

204. Manufacturing a second number of second light-transmitting portions when the preset inclination angle is within the second preset range; wherein a minimum value of the first preset range is larger than a maximum value of the second preset range, and the first number is less than the second number.

When the preset inclination angle of the first inclined wall 3112 is within the second preset range, the second number of second light-transmitting portions 602 are manufactured. The minimum value of the first preset range is larger than the maximum value of the second preset range, and the first number is less than the second number. That is, the number of the second light-transmitting portions 602 of the photomask 6 can be adjusted, so as to adjust the inclination angle θ of the first inclined wall 3112. The more the number of the second light-transmitting portions 602 is, the gentler the inclination angle θ of the first side walls 311 becomes.

Illustratively, the first inclination wall 3112 manufactured by the photomask 6 having no second light-transmitting portion 602 has a first inclination angle θ1, which is relatively large, resulting in poor diffuse reflection occurring on the reflective layer 40. The first inclined wall 3112 manufactured by the photomask 6 having one second light-transmitting portion 602 has a second inclination angle θ2, which is less than the first inclination angle θ1, thereby improving the diffuse reflection effect on the reflective layer 40. Further, the first inclined wall 3112 manufactured by the photomask 6 having two second light-transmitting portions 602 has a third inclination angle θ3, which is less than the second inclination angle θ2, thereby obtaining more desirable diffuse reflection effect on the reflective layer 40. Thus, the shape of the photomask 6 can be set according to an actual situation so that the organic layer 30 manufactured by the photomask 6 conforms to the preset conditions.

With continued reference to FIG. 3, in another embodiment, manufacturing the photomask 6 according to the preset inclination angle includes the following steps:

301. Preparing a light-shielding material.

Referring to step 201, details are not described herein.

302. Disposing the light-transmitting region on the light-shielding material, wherein the light-transmitting region includes the plurality of first light-transmitting portions and at least one annular second light-transmitting portion disposed around each of the first light-transmitting portions. Each of the first light-transmitting portions includes the first outer edge adjacent to the corresponding second light-transmitting portion, and each of the at least one second light-transmitting portion includes the inner edge adjacent to the corresponding first light-transmitting portion and the second outer edge away from the first light-transmitting portion. The distance between the first outer edge and the inner edge is the first length, and the distance between the inner edge and the second outer edge is the second length.

The light-transmitting region is disposed on the light-shielding material. The light-transmitting region may include the plurality of first light-transmitting portions 601 and at least one annular second light-transmitting portion 602 disposed around each of the first light-transmitting portions 601.

Each of the first light-transmitting portions 601 includes the first outer edge adjacent to the corresponding second light-transmitting portion 602, each of the at least one second light-transmitting portion 602 includes the inner edge adjacent to the corresponding first light-transmitting portion 601 and the second outer edge away from the corresponding first light-transmitting portion 601. The distance between the first outer edge and the inner edge is the first length L1, and the distance between the inner edge and the second outer edge is the second length L2. Both of the first length L1 and the second length L2 are greater than 0.

303. Making the ratio of the first length to the second length be a first ratio when the preset inclination angle is within the third preset range.

When the preset inclination angle is within the third preset range, the ratio of the first length L1 to the second length L2 is the first ratio, wherein the first ratio is greater than 0.

304. Making the ratio of the first length to the second length be a second ratio when the preset inclination angle is within a fourth preset range; wherein the minimum value of the third preset range is greater than the maximum value of a fourth preset range, and the first ratio is greater than the second ratio.

When the preset inclination angle is within the fourth preset range, the ratio of the first length L1 to the second length L2 is the second ratio. The minimum value of the third preset range is greater than the maximum value of the fourth preset range, and the first ratio is greater than the second ratio. That is, in the embodiment of the present disclosure, the ratio of the first length L1 to the second length L2 in the photomask 6 can be controlled to adjust the inclination angle θ of the first inclined wall 3112. The less the ratio of the first length L1 to the second length L2 is, the gentler the inclination angle θ of the first inclined wall 3112 becomes.

Illustratively, when the ratio of the first length L1 to the second length L2 in the photomask 6 is 2:1, the inclination angle θ of the first inclined wall 3112 is the first inclination angle θ1, which is relatively large, leading to undesirable reflection effect. When the ratio of the first length L1 to the second length L2 in the photomask 6 is 1.7:1.3, the inclination angle θ of the first inclination wall 3112 is the second inclination angle θ2, which is less than the first inclination angle θ, leading to improvement of reflection effect of the reflection layer 40 to ambient light. When the ratio of the first length L1 to the second length L2 in the photomask 6 is 1:2, the inclination angle θ of the first inclined wall 3112 is the third inclination angle θ3, which is less than the second inclination angle θ2, further leading to more desirable reflection effect of the reflection layer 40 to ambient light. It is to be noted that the ratio of the first length L1 to the second length L2 in the photomask 6 is specifically set according to an actual situation, and is not specifically limited herein.

It is to be understood that, when the photomask 6 is manufactured, the ratio of the first length L1 to the second length L2 in the photomask 6 may be controlled on the basis of the control of the number of the second light-transmitting portions 602, or the number of the second light-transmitting portions 602 may be controlled on the basis of the control of the ratio of the first length L1 to the second length L2 in the photomask 6, so that the inclination angle θ of the first inclined wall 3112 conforms to the preset inclination angle. A specific design of the number of the second light-transmitting portions 602 and the ratio of the first length L1 to the second length L2 may be set in accordance with an actual application, which is not specifically limited herein.

With continued reference to FIG. 4, in another embodiment, manufacturing the photomask 6 according to the preset inclination angle further includes the following steps:

401. Patterning a plurality of stripe-shaped third light-transmitting portions on the light-shielding material, wherein the third light-transmitting portions are arranged in parallel along a length direction.

The plurality of stripe-shaped third light-transmitting portions 603 may be patterned on the light-shielding material, wherein the third light-transmitting portions 603 are arranged in parallel in the length direction so as to thin the protrusions of the photomask 6, thereby decreasing the inclination angle θ of the first inclined wall 3112.

402. Manufacturing a third number of third light-transmitting portions when the preset inclination angle is within a fifth preset range.

When the preset inclination angle is within the fifth preset range, the third number of third light-transmitting portions 603 are manufactured, wherein the third number is greater than or equal to 1.

403. Manufacturing a fourth number of third light-transmitting portions when the preset inclination angle is within a sixth preset range, wherein the minimum value of the fifth preset range is greater than the maximum value of the sixth preset range, and the third number is greater than the fourth number.

When the preset inclination angle is within the sixth preset range, the fourth number of third light-transmitting portions 603 are manufactured, wherein the minimum value of the fifth preset range is greater than the maximum value of the sixth preset range, and the third number is greater than the fourth number. That is, the inclination angle θ of the first side wall 311 can be adjusted by adjusting the number of the third light-transmitting portions 603. The more the number of the third light-transmitting portions 603 is, the gentler the inclination angle θ of the first side wall 311 becomes. The number of the third light-transmitting portions 603 may be specifically set according to an actual condition, and is not specifically limited herein.

In other embodiments, a distance between two adjacent third light-transmitting portions 603 is a third length, and a width of each of the third light-transmitting portions 603 is a fourth length. A third ratio of the third length to the fourth length can be controlled to adjust the inclination angle θ of the first inclined wall 3112. The less the third ratio is, the gentler the inclination angle θ of the first inclined walls 3112 is.

During manufacturing of the display panel 100, the liquid crystal layer, a color film substrate, and a polarizer are sequentially disposed on a side of the reflective layer 40 away from the driving element layer, so as to form the display panel 100. Since the display panel 100 of the embodiment of the present disclosure utilizes the reflective layer 40 to reflect ambient light for displaying, the polarizer needs to be attached only on a single side, thereby saving materials.

In an embodiment of the present disclosure, the second convex structures 410 are formed on the reflective layer 40, and the inclination angle θ of the second inclined wall of each of the second convex structures 410 is changed by designing different photomasks 6, so as to increase the diffuse reflection of the reflective layer 40, and improve the reflectivity. In addition, the display using total reflection may remove the backlight source, so that the product has the advantages of low power consumption, and lightness and thinness. The reflective layer 40 is used to reflect the ambient light to achieve reflective displaying, thereby realizing a daylight readable function. The display brightness has a certain eye-protecting effect for the user because it depends on the brightness of ambient light.

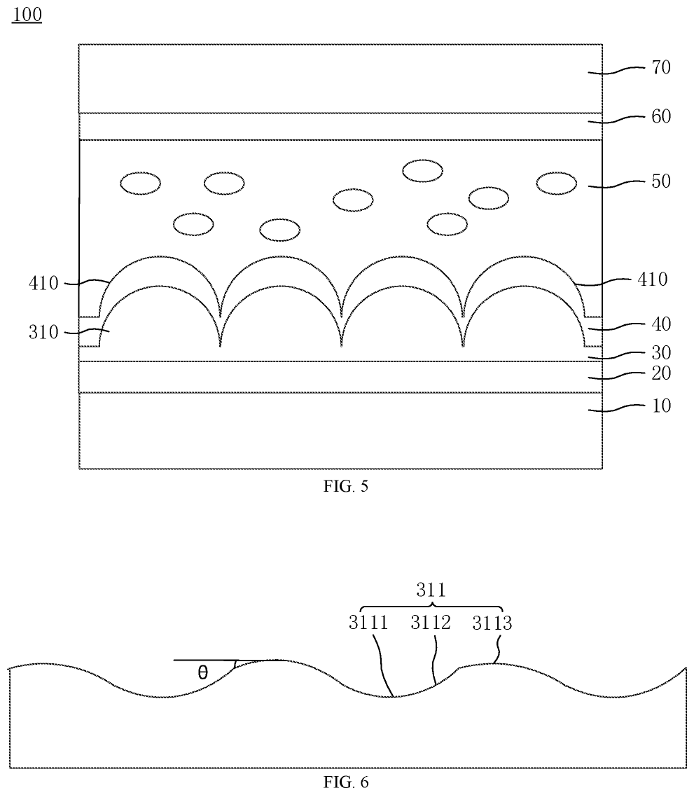

With continued reference to FIGS. 5 and 6, FIG. 5 is a schematic structural diagram of a display panel according to an embodiment of the present disclosure. FIG. 6 is a schematic structural diagram of first convex structures in the display panel shown in FIG. 5. An embodiment of the present disclosure provides a display panel 100, which may be a liquid crystal display (LCD). The configuration of the LCD includes a liquid crystal cell disposed between two parallel glass substrates, a thin film transistor (TFT) disposed on the lower glass substrate, and a color filter disposed on the upper glass substrate. A rotation direction of liquid crystal molecules is controlled by changing a signal and a voltage on the TFT, thereby controlling whether the polarized light of each pixel is emitted or not to achieve the display purpose.

Illustratively, the display panel 100 may include a substrate 10, the driving element layer 20, the organic layer 30, and the reflective layer 40. The driving element layer 20 is disposed on a side of the substrate 10. The organic layer 30 is disposed on a side of the driving element layer 20 away from the substrate 10. The organic layer 30 includes the plurality of first convex structures 310, and each of the first convex structures 310 has the arcuate first side wall 311 from bottom to top. The first side wall 311 includes the bottom wall 3111, the first inclined wall 3112, and the outer wall 3113 which are connected in sequence. The reflective layer 40 is disposed on the side of the organic layer 30 away from the driving element layer 20, The reflective layer 40 includes the plurality of second convex structures 410, and each of the second convex structures 410 includes the second side wall corresponding to the first side wall 311. The second side wall is capable of reflecting ambient light to the display surface of the display panel 100.

The inclination angle of the first inclined wall is in a range of greater than 0° and less than or equal to 10°.

The second side wall includes the second inclined wall corresponding to the first inclined wall. In some embodiments, the inclination angle of the second inclined wall is equal or substantially equal to the inclination angle of the first inclined wall. It is to be noted that, the inclination angle of the second inclined wall being substantially equal to the inclination angle of the first inclined wall can be understood as the difference between the inclination angle of the second inclined wall and the inclination angle of the first inclined wall being within a preset difference range. The preset difference range needs to be set according to a manufacturing process or an actual application, and is not specifically limited herein.

A curvature of the first side wall is greater than a curvature of the second side wall. By setting the curvature of the first side wall to be greater than the curvature of the second side wall, the inclination angle of the second inclined wall and the inclination angle of the first inclined wall are equal or substantially equal to each other.

In other embodiments, the curvature of the first side wall may be less than or equal to the curvature of the second side wall. The inclination angle of the second inclined wall is adjusted by adjusting the curvature of the second side wall.

Each of the first convex structures includes a first convex ring connected to the outer wall, and each of the second convex structures includes a second convex ring corresponding to the first convex ring. In some embodiments, the diameter of the second convex ring is less than the diameter of the first convex ring. By this arrangement, the inclination angle of the second inclined wall and the inclination angle of the first inclined wall can be equal or substantially equal to each other.

In other embodiments, the diameter of the second convex ring may be greater than or equal to the diameter of the first convex ring. The inclination angle of the second inclined wall can be adjusted by adjusting the diameter of the second convex ring.

The plurality of second convex structures are formed on the reflective layer. In some embodiments, the plurality of second convex structures are arranged in an array. In other embodiments, the plurality of second convex structures are arranged in M rows by N columns, and the second convex structures in two adjacent rows are arranged in a staggered manner. Both of M and N are integers greater than 0.

The display panel 100 may further include the color film substrate 60, the liquid crystal layer 50 and the polarizer 70. The color film substrate 60 is disposed opposite to the driving element layer 20. The liquid crystal layer 50 is disposed between the driving element layer 20 and the color film substrate 60. The reflective layer 40 is disposed on the side of the driving element layer 20 facing the liquid crystal layer 50. The polarizer 70 is disposed on a side of the color film substrate 60 away from the substrate 10. The driving element layer 20 may include a plurality of driving TFTs. The liquid crystal layer 50 may include a plurality of liquid crystal molecules. The color film substrate 60 may include a color filter. The driving TFTs are configured to drive the liquid crystal molecules to rotate. Light passes through the liquid crystal layer 50 then the color film substrate 60, and then reaches to the display surface of the display panel 100. Different colors can be display through the color film substrate 60, so that the display panel 100 shows different display effects.

LCD display screens may be divided into transmissive screens and reflective screens. The transmissive LCDs need a backlight source, and the reflective LCDs use ambient light as a light source. Reflective LCDs have the advantages of light weight of body and low power consumption, and are increasingly used in outdoor scenes. However, the reflectivity of the current reflective liquid crystal display panel 100 is relatively low, and a maximum level of 10% or less in mass production in the industry can be achieved. The main reason for the low reflectivity is that light is reflected through multiple paths and has serious energy loss, and finally, the amount of light emitted is only 10% of the amount of incident light.

In an embodiment of the present disclosure, in order to solve the problem of low reflectivity of the existing liquid crystal display panel 100 to ambient light, the reflective layer 40 may be disposed in the display panel 100. The reflective layer 40 may be made of a metal material having a high reflectivity. For example, the reflective layer 40 may be made of gold (Au), silver (Ag), copper (Cu), aluminum (Al), or the like. When the metal material used is easily oxidized, for example, Ag, indium tin oxide (ITO) layer having a certain thickness can be deposited on the top and bottom of the Ag film layer for protection, as Ag is prone to oxidation. Certainly, if a metal material that is not easily oxidized is used, the upper and lower ITO layers can be removed.

Illustratively, the reflective layer 40 is disposed on the side of the driving element layer 20 facing the liquid crystal layer 50. It is to be understood that with the ambient light as the light source, the liquid crystal molecules of the liquid crystal layer 50 can be used as a switch, the reflective layer 40 is disposed on the side of the driving element layer 20 facing the liquid crystal layer 50, and the amount of light emitted from the reflective layer 40 can be controlled by the liquid crystal molecules, thereby controlling parameters of the display panel 100 such as grayscale or brightness. Furthermore, the reflective layer 40 is separated from the driving element layer 20, so that the manufacturing of the driving element layer 20 and the reflective layer 40 can be facilitated and the processes are compatible.

By forming the plurality of second convex structures 410 on the reflective layer 40, the second side wall of each of the second convex structures 410 can reflect ambient light to the display surface of the display panel 100. The formation of the second convex structures 410 can increase the diffuse reflection to the ambient light and reduce the influence of the total reflection on the reflectivity of the reflective layer 40, thereby improving the reflectivity of the display panel 100 to the ambient light.

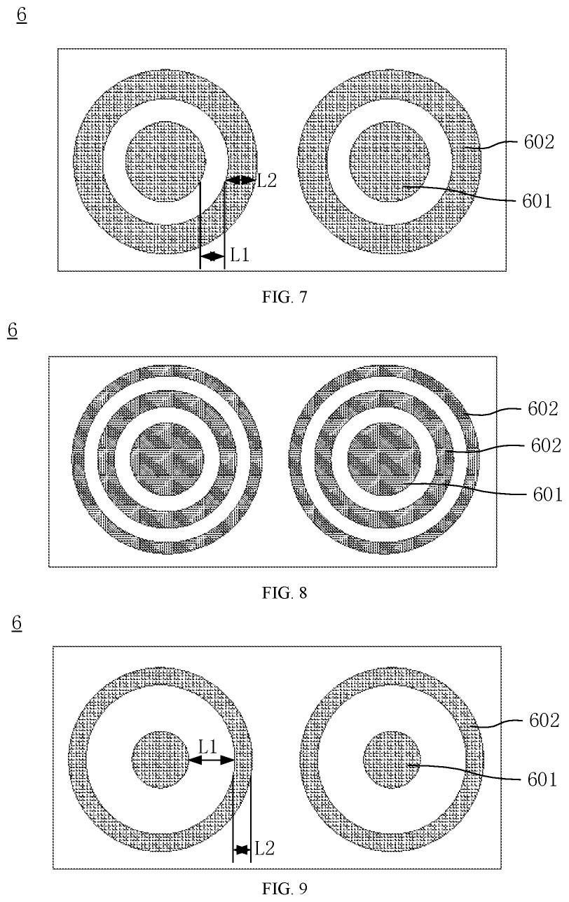

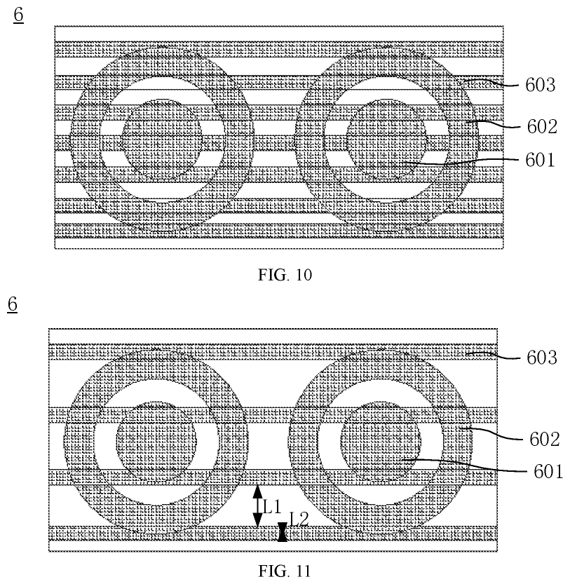

With continued reference to FIGS. 7 to 11, FIG. 7 is a schematic diagram of a first configuration of a photomask according to an embodiment of the present disclosure, FIG. 8 is a schematic diagram of a second configuration of a photomask according to an embodiment of the present disclosure, FIG. 9 is a schematic diagram of a third configuration of a photomask according to an embodiment of the present disclosure, FIG. 10 is a schematic diagram of a fourth configuration of a photomask according to an embodiment of the present disclosure, and FIG. 11 is a schematic diagram of a fifth configuration of a photomask according to an embodiment of the present disclosure. An embodiment of the present disclosure further provides the photomask 6 for fabricating the organic layer 30 of the display panel 100. The photomask 6 includes a light-transmitting layer and a light-shielding layer. The light-transmitting layer allows an ultraviolet light to transmit. The light-transmitting layer includes the first light-transmitting portion 601 and at least one annular second light-transmitting portion 602 around the first light-transmitting portion 601. The light-shielding layer is disposed in an area adjacent to the first light-transmitting portion 601 and the corresponding second light-transmitting portion 602, and configured to shield an ultraviolet light. The specific pattern of the photomask 6 may be designed according to an actual condition, and is not specifically limited herein.

Illustratively, a pattern of the photomask 6 may be designed to have a different number of second light-transmitting portions 602, so as to produce different shapes of the organic layer 30. For example, as shown in FIG. 7, the photomask 6 includes a circular first light-transmitting portion 601, and an annular second light-transmitting portion 602 around the first light-transmitting portion 601. As shown in FIG. 8, the photomask 6 includes a circular first light-transmitting portion 601, and two annular second light-transmitting portions 602 around the first light-transmitting portion 601. The plurality of second light-transmitting portions 602 may have any shapes. The specific description may refer to the foregoing description, and details are not repeated herein.

The pattern of the photomask 6 may be designed to have different ratios of the first length L1 to the second length L2 to produce different shapes of the organic layer 30. For example, as shown in FIG. 7, the ratio of the first length L1 to the second length L2 provided in the photomask 6 is the first ratio. As shown in FIG. 9, the ratio of the first length L1 to the second length L2 provided in the photomask 6 is the second ratio, wherein the first ratio is less than the second ratio.

The pattern of the photomask 6 may be designed to have a different number of stripe-shaped third light-transmitting portions 603 to produce different shapes of the organic layer 30. For example, as shown in FIG. 10, a plurality of third light-transmitting portions 603 are disposed parallel to each other along the length direction of the photomask 6. As shown in FIG. 11, the distance between two adjacent third light-transmitting portions 603 is the third length, and the width of each of the third light-transmitting portions 603 is the fourth length. The shape of the organic layer 30 may be adjusted by adjusting the ratio of the third length to the fourth length.

The specific design for the pattern of the photomask 6 may be set according to an actual situation, and is not specifically limited herein, as long as the organic layer 30 produced through the photomask 6 can conform to the preset conditions.

The method of manufacturing the display panel, the display panel, and the photomask according to the embodiments of the present disclosure are described in detail above. The principles and embodiments of the present disclosure have been described with reference to specific examples, and the explanation of the above examples is provided to help understand the present disclosure. Meanwhile, variations will occur to those skilled in the art in both the detailed description and the scope of application in accordance with the teachings of the present disclosure. In summary, the present description should not be construed as limiting the present disclosure.

What is claimed is:

1. A display panel, comprising:
a substrate;
a driving element layer disposed on a surface of the substrate;
an organic layer disposed on a surface of the driving element layer away from the substrate, wherein the organic layer comprises a plurality of first convex structures, and each of the first convex structures has an arcuate first sidewall from bottom to top;
a reflective layer disposed on a side of the organic layer away from the driving element layer, wherein the reflective layer comprises a plurality of second convex structures, each of the second convex structures comprises a second side wall corresponding to the first side wall.

2. The display panel according to claim 1, wherein the first side wall comprises a bottom wall, a first inclined wall, and an outer wall connected in sequence, and an inclination angle of the first inclined wall is in a range of greater than 0° and less than or equal to 10°.

3. The display panel according to claim 2, wherein the second side wall comprises a second inclined wall corresponding to the first inclined wall, and an inclination angle of the second inclined wall is equal or substantially equal to the inclination angle of the first inclined wall.

4. The display panel according to claim 3, wherein a curvature of the first side wall is greater than a curvature of the second side wall.

5. The display panel according to claim 3, wherein each of the first convex structures comprises a first convex ring connected to the outer wall, each of the second convex structures comprises a second convex ring corresponding to the first convex ring, and a diameter of the second convex ring is less than a diameter of the first convex ring.

6. The display panel according to claim 1, wherein the plurality of second convex structures are arranged in an array; or
the plurality of second convex structures are arranged in M rows by N columns, the second convex structures in two adjacent rows are arranged in a staggered manner, and both of M and N are integers greater than 0.

7. A method of manufacturing a display panel, comprising:
disposing a material of an organic layer on a driving element layer;
treating the material of the organic layer with a photomask to form the organic layer having a plurality of first convex structures, wherein each of the first convex structures has an arcuate first sidewall from bottom to top, the first sidewall comprises a bottom wall, a first inclined wall, and an outer wall connected in sequence, and the first inclined wall has an inclination angle less than a preset inclination angle;
disposing a reflective layer on a side of the organic layer away from the driving element layer, wherein the reflective layer comprises a plurality of second convex structures, each of which corresponds to each of the first convex structures, and each of the second convex structures comprises a second side wall corresponding to the first side wall.

8. The method according to claim 7, wherein the inclination angle of the first inclined wall is in a range of greater than 0° and less than or equal to 10°.

9. The method according to claim 7, wherein the step of disposing the reflective layer on the side of the organic layer away from the driving element layer comprises:
disposing a reflective material on a side of the first inclined wall away from the driving element layer to form a second inclined wall, wherein the second inclined wall has an inclination angle equal to or substantially equal to the inclination angle of the first inclined wall.

10. The method according to claim 7, wherein each of the first convex structures comprises a first convex ring connected to the outer wall, each of the second convex structures comprises a second convex ring corresponding to the first convex ring, and a diameter of the second convex ring is less than a diameter of the first convex ring.

11. The method according to claim 7, wherein the second convex structures are arranged in an array; or
the second convex structures are arranged in M rows by N columns, the second convex structures in two adjacent rows are arranged in a staggered manner, and both of M and N are integers greater than 0.

12. A photomask for fabricating an organic layer in a display panel, comprising:
a light-transmitting layer comprising a first light-transmitting portion and at least one annular second light-transmitting portion disposed around the first light-transmitting portion;
a light-shielding layer disposed in an area adjacent to the first light-transmitting portion and the second light-transmitting portion.

13. The photomask according to claim 12, wherein the light-transmitting layer further comprises:
a plurality of stripe-shaped third light-transmitting portions, wherein the plurality of third light-transmitting portions are arranged parallel to each other along a length direction of the photomask.
